(19) United States
(12) Patent Application Publication
(10) Pub. No.: US 2024/0234453 A9
(43) Pub. Date: Jul. 11, 2024

(54) IMAGE SENSOR

(71) Applicant: SAMSUNG ELECTRONICS CO., LTD., Suwon-si (KR)

(72) Inventor: Masato FUJITA, Suwon-si (KR)

(21) Appl. No.: 18/381,908

(22) Filed: Oct. 19, 2023

(30) Foreign Application Priority Data
Oct. 20, 2022 (KR) 10-2022-0135647

(51) Int. Cl. H01L 27/146

(52) U.S. Cl. CPC H01L 27/14614; H01L 27/1463; H01L 27/14645; H01L 27/14689

(57) ABSTRACT

An image sensor, comprising a semiconductor substrate having first and second surfaces opposed to each other, a photoelectric conversion region in the semiconductor substrate, a floating diffusion region adjacent to the first surface in the semiconductor substrate, and a vertical transfer gate on the first surface of the semiconductor substrate, and extending in a direction perpendicular to the first surface and connected to the photoelectric conversion region. The vertical transfer gate may transfer photocharges collected in the photoelectric conversion region to the floating diffusion region. The vertical transfer gate includes a first vertical electrode portion and a second vertical electrode portion extending from the first surface of the semiconductor substrate in the vertical direction, and connected to the photoelectric conversion region, respectively.

### CROSS-REFERENCE TO RELATED APPLICATION

Korean Patent Application No. 10-2022-0135647, filed on Oct. 20, 2022, with the Korean Intellectual Property Office, is incorporated herein by reference.

### BACKGROUND

### 1. Field

An image sensor is disclosed.

### 2. Description of the Related Art

An image sensor is a device converting an optical image signal into an electrical signal. The image sensor has a plurality of pixels, each pixel including a photoelectric conversion region (e.g., photodiode) receiving incident light and converting the light into an electrical signal, and a pixel circuit outputting a pixel signal using charges generated in a diode region.

### SUMMARY

Embodiments are directed to an image sensor which may include a semiconductor substrate having first and second surfaces opposed to each other, a photoelectric conversion region in the semiconductor substrate, a floating diffusion region adjacent to the first surface in the semiconductor substrate, a vertical transfer gate VTG on the first surface of the semiconductor substrate, extending in a direction, perpendicular to the first surface and connected to the photoelectric conversion region, transferring photocharges collected in the photoelectric conversion region to the floating diffusion region, wherein the vertical transfer gate may include a first vertical electrode portion and a second vertical electrode portion extending from the first surface of the semiconductor substrate in the vertical direction, and connected to the photoelectric conversion region, respectively, and an electrode pad portion on the first surface of the semiconductor substrate, connected to the first and second vertical electrode portions, and having a concave portion in a region, adjacent to the floating diffusion region.

Embodiments are also directed to an image sensor which may include a semiconductor substrate having first and second surfaces opposed to each other and having a plurality of pixels arranged thereon, a first isolation structure penetrating through the semiconductor substrate, and defining the plurality of pixels, and a second isolation structure penetrating through the semiconductor substrate, and dividing each of the plurality of pixels into a first sub-pixel and a second sub-pixel, wherein the image sensor may include a first photoelectric conversion region and a second photoelectric conversion region in the semiconductor substrate, and respectively located in the first sub-pixel and the second sub-pixel of each of the plurality of pixels, a first floating diffusion region and a second floating diffusion region adjacent to the first surface in the semiconductor substrate, and respectively located in the first sub-pixel and the second sub-pixel of each of the plurality of pixels, and a first vertical transfer gate, in the first sub-pixel of each of the plurality of pixels, the first vertical transfer gate may have a first pair of vertical electrode portions extending from the first surface and connected to the first photoelectric conversion region, and a first electrode pad portion respectively connected to the first pair of vertical electrode portions on the first surface, and may have a first concave portion in a region, adjacent to the first floating diffusion region, the first electrode pad portion may have a second vertical transfer gate, in the second sub-pixel of each of the plurality of pixels, the second vertical transfer gate may have a second pair of vertical electrode portions extending from the first surface and connected to the second photoelectric conversion region, and a second electrode pad portion respectively connected to the second pair of vertical electrode portions on the first surface, and may have a second concave portion in a region, adjacent to the second floating diffusion region.

Embodiments are also directed to an image sensor which may include a semiconductor substrate having first and second surfaces facing each other and having a plurality of pixels arranged thereon, a first isolation structure on the semiconductor substrate, and defining the plurality of pixels, a second isolation structure penetrating through the semiconductor substrate, and dividing each of the plurality of pixels into a plurality of sub-pixels, and a plurality of photoelectric conversion regions in the semiconductor substrate in each of the plurality of sub-pixels, the image sensor may include a plurality of vertical transfer gates respectively on the plurality of photoelectric conversion regions on the first surface of the semiconductor substrate, and respectively connected to the plurality of photoelectric conversion regions, and a common floating diffusion region coupled to the plurality of vertical transfer gates, wherein each of the plurality of vertical transfer gates may include first and second vertical electrode portions extending from the first surface of the semiconductor substrate in a direction, perpendicular to the first surface, and connected to each of the plurality of photoelectric conversion regions, an electrode pad portion on the first surface of the semiconductor substrate, connected to the first and second vertical electrode portions, and may have a concave portion in a region, adjacent to the common floating diffusion region.

### BRIEF DESCRIPTION OF DRAWINGS

Features will become apparent to those of skill in the art by describing in detail exemplary embodiments with reference to the attached drawings in which:

FIG. 1 is a layout diagram illustrating an image sensor according to an example embodiment.

FIG. 2 is a layout diagram of a pixel array corresponding to portion “I” of the image sensor of FIG. 1.

FIG. 3 is a circuit diagram of a pixel array corresponding to portion “I” of the image sensor of FIG. 1.

FIGS. 4A to 4C are cross-sectional views taken along lines D1-D1′, D2-D2′, and D3-D3′ of FIG. 3, respectively.

FIG. 5 is a partially enlarged view illustrating portion “A” of the image sensor of FIG. 3.

FIG. 6 is a partially enlarged view illustrating portion “B” of the image sensor of FIG. 4B.

FIGS. 7A to 7D are partial layout views illustrating image sensors according to various example embodiments.

FIGS. 8A to 8D are main process cross-sectional views illustrating a method of manufacturing an image sensor according to an example embodiment.

FIG. 9 is a partial layout diagram illustrating an image sensor according to an example embodiment.

FIG. 10 is a partial layout diagram illustrating an image sensor according to an example embodiment.

### DETAILED DESCRIPTION

Hereinafter, preferred embodiments will be described with reference to the accompanying drawings. Hereinafter, terms such as ‘an upper side, ‘an upper portion,’ ‘an upper surface,’ a lower side, a lower portion, a lower surface, and the like, may be understood as referring to the drawings, except where otherwise indicated by reference numerals.

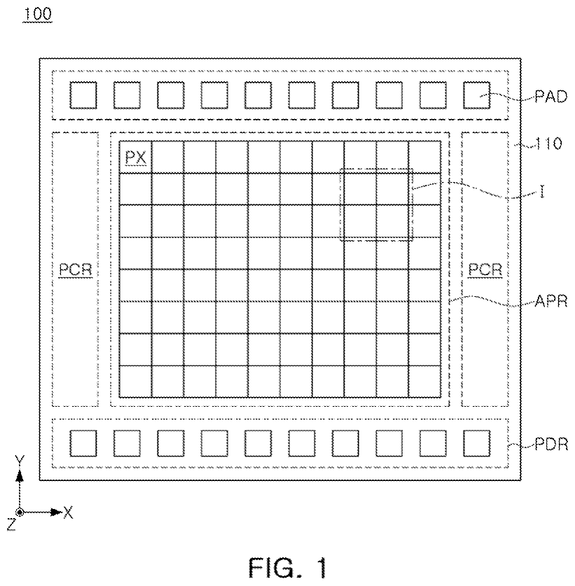

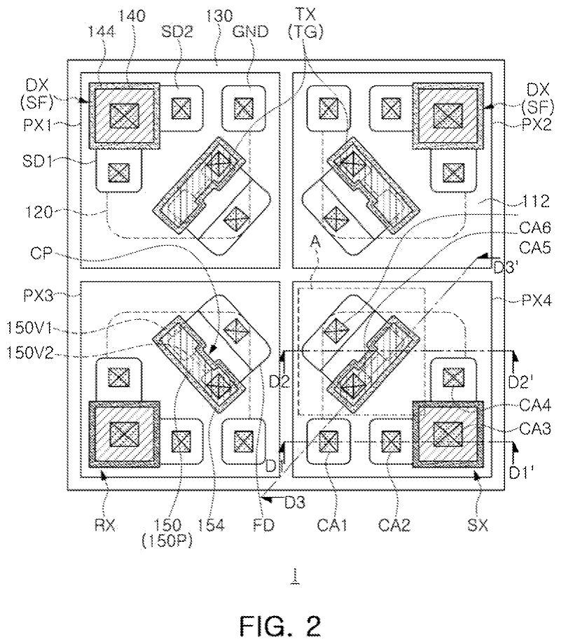

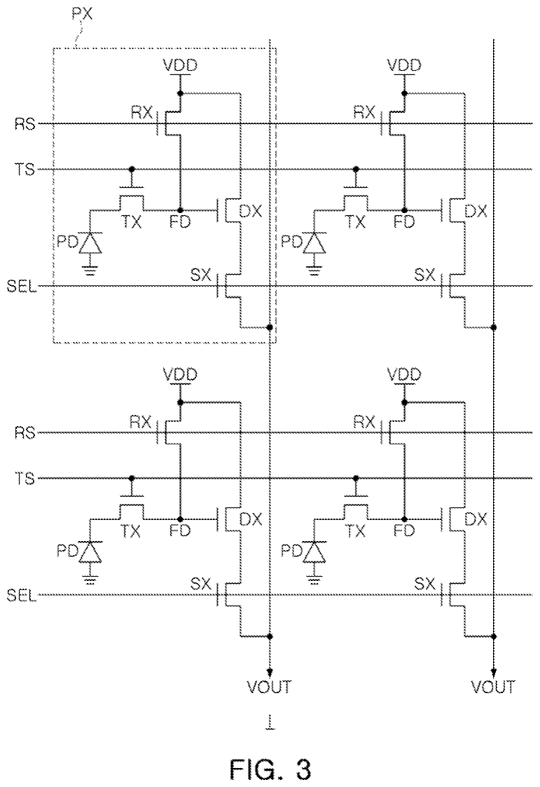

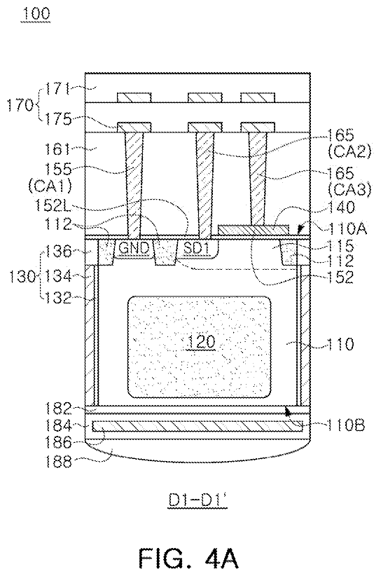

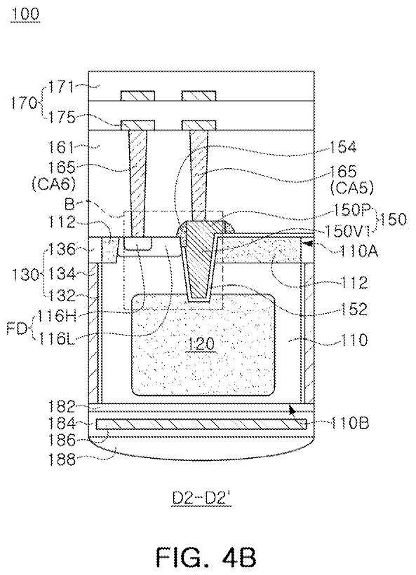

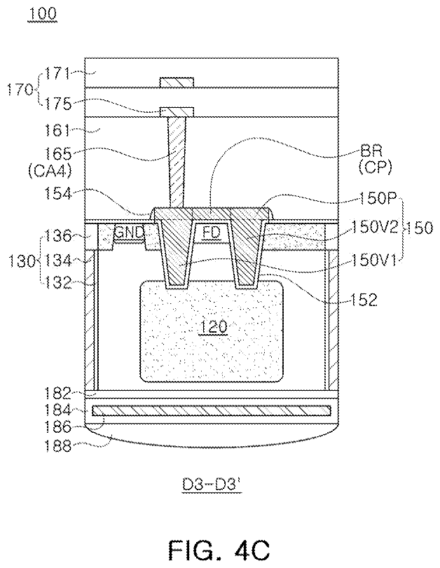

FIG. 1 is a layout diagram illustrating an image sensor according to an example embodiment, FIGS. 2 and 3 are circuit diagrams and layout diagrams of a pixel array corresponding to an “I” portion of the image sensor of FIG. 1, and FIGS. 4A to 4C are cross-sectional views taken along lines D1-D1′, D2-D2′, and D3-D3′ of FIG. 3, respectively.

Referring to FIGS. 1 to 3, an image sensor 100 according to the present embodiment may include an active pixel region APR, a peripheral circuit region PCR, and a pad region PDR formed on a semiconductor substrate 110.

The active pixel region APR may be in a central portion of the semiconductor substrate 110, and a peripheral circuit region PCR may be on both sides of the active pixel region APR. A pad region PDR may be in an edge portion of the semiconductor substrate 110.

The active pixel region APR may include a plurality of pixels PX, and as illustrated in FIGS. 2 and 4A to 4C, a plurality of photoelectric conversion regions 120 may be in each of the plurality of pixels PX. In the active pixel region APR, the plurality of pixels PX may be arranged in a matrix shape forming columns and rows in a first direction (X), parallel to an upper surface of the semiconductor substrate 110, and a second direction (Y), perpendicular to the first direction and parallel to the upper surface of the semiconductor substrate 110.

The peripheral circuit region PCR is illustrated as being on both sides of the active pixel region APR in plan view and may surround the entire active pixel region APR. In some example embodiments, the peripheral circuit region PCR may be formed on another substrate and connected to a substrate having the active pixel region APR formed thereon in stack form. A conductive pad PAD may be in the pad region PDR. The conductive pad PAD may be on an edge portion of the semiconductor substrate 110.

As illustrated in FIGS. 4A to 4C, the semiconductor substrate 110 may include a first surface 110A and a second surface 110B, opposite to each other. Here, for convenience of description, a surface of the semiconductor substrate 110 on which a color filter 186 is disposed is referred to as the second surface 110B, and a surface opposite to the second surface 110B is referred to as the first surface 110A. In some example embodiments, the semiconductor substrate 110 may include a P-type semiconductor substrate. In an implementation, the semiconductor substrate 110 may include Si, Ge, SiGe, SiC, GaAs, InAs, or InP. In an implementation, the semiconductor substrate 110 may be formed of a P-type silicon substrate. In some example embodiments, the semiconductor substrate 110 may include a P-type bulk substrate and a P-type or N-type epitaxial layer grown thereon. In other example embodiments, the semiconductor substrate 110 may include an N-type bulk substrate and a P-type or N-type epitaxial layer grown thereon. Alternatively, the semiconductor substrate 110 may be formed of an organic plastic substrate. A well region 115 may be inside the semiconductor substrate 110, adjacent to the first surface 110A of the semiconductor substrate 110. The well region 115 may be a region doped with P-type impurities. As used herein, the term “or” is not an exclusive term, e.g., “A or B” would include A, B, or A and B.

A plurality of pixels PX may be arranged in matrix form within the semiconductor substrate 110 in the active pixel region APR. A plurality of photoelectric conversion regions 120 may be in each of the plurality of pixels PX. The plurality of photoelectric conversion regions 120 may be regions in which light incident from the second surface 110B of the semiconductor substrate 110 may be converted into an electrical signal.

An isolation structure 130 may be within the semiconductor substrate 110 in the active pixel region APR, and a plurality of pixels PX may be defined by the isolation structure 130. The isolation structure 130 may be between one of the plurality of photoelectric conversion regions 120 and a photoelectric conversion region 120 adjacent thereto. One photoelectric conversion region 120 and another photoelectric conversion region 120, adjacent thereto may be physically and electrically isolated by the isolation structure 130.

The isolation structure 130 may have a grid or mesh shape, positioned between each of the plurality of photoelectric conversion regions 120 arranged in a matrix form when viewed in plan view. The isolation structure 130 may be formed in an isolation trench penetrating through the semiconductor substrate 110 from the first surface 110A to the second surface 110B of the semiconductor substrate 110. The isolation structure 130 may include an insulating film 132 conformally formed on a sidewall of the isolation trench penetrating through the semiconductor substrate 110 and a filling conductive layer filling an inside of the isolation trench on the insulating film 132, and an upper insulating layer 136. The upper insulating layer 136 may be in a portion of the isolation trench, adjacent to the first surface 110A of the semiconductor substrate 110. In example embodiments, the upper insulating layer 136 may be formed by etching rear portions of the insulating film 132 and the filling conductive layer 134 disposed at an entrance of the isolation trench and filling a remaining space with an insulating material. In some example embodiments, the insulating layer 132 may include a metal oxide such as hafnium oxide, aluminum oxide, or tantalum oxide. In this case, the insulating film 132 may act as a negative fixed charge layer. In other example embodiments, the insulating film 132 may include an insulating material such as silicon oxide, silicon nitride, or silicon oxynitride. In an implementation, the filling conductive layer 134 may include doped polysilicon, a metal, a metal silicide, a metal nitride, or a metal-containing film.

FIGS. 4A to 4C exemplarily illustrate that the isolation structure 130 extends through the semiconductor substrate 110 from the first surface 110A to the second surface 110B of the semiconductor substrate 110. Conversely, in other example embodiments, the isolation structure 130 may extend from the second surface 110B of the semiconductor substrate 110 toward an inside of the semiconductor substrate 110 and may not be exposed to the first surface 110A of the semiconductor substrate 110. In this case, a barrier doped region may be formed between one end of the isolation structure 130, adjacent to the first surface 110A of the semiconductor substrate 110 and the first surface 110A, and the barrier doped region may be a region heavily doped with P-type impurities.

As illustrated in FIGS. 4A to 4C, a device isolation film 112 defining an active region may be formed on the first surface 110A of the semiconductor substrate 110. The device isolation film 112 may be formed to a predetermined depth on the first surface 110A of the first semiconductor substrate 110, and may include an insulating material. The device isolation layer 112 may surround an upper sidewall (e.g., a sidewall of the upper insulating layer 136) of the isolation structure 130.

Transistors constituting a pixel circuit (see FIG. 3) may be on the active region. The active region may be a portion of the semiconductor substrate 110 on which a transfer transistor TX, a drive transistor DX, a selection transistor SX, and a reset transistor RX may be disposed thereabove. In an implementation, the active region may include a ground region GND, a floating diffusion region FD, and first and second source/drain regions SD1 and SD2. The ground region GND, the floating diffusion region FD, and the first and second source/drain regions SD1 and SD2 may be spaced apart from each other by the device isolation layer 112.

In some example embodiments, as illustrated in FIG. 2, the first pixel PX1, the second pixel PX2, the third pixel PX3, and the fourth pixel PX4 may be arranged in a matrix shape, the first pixel PX1 and the third pixel PX3, disposed side by side in the second direction (Y) may have a mirror symmetrical shape with each other, and the first pixel PX1 and the second pixel PX2, disposed side by side in the first direction (X) may have mirror symmetrical shape with each other.

In some example embodiments, as illustrated in FIG. 2, the first pixel PX1 and the second pixel PX2 may include a transfer transistor TX and a drive transistor DX, the third pixel PX3 may include a transfer transistor TX and a reset transistor RX, and the fourth pixel PX4 may include a transfer transistor TX and a select transistor SX.

FIG. 3 is a circuit diagram of the 4×4 pixel array of FIG. 2. Referring to FIG. 3, each of unit pixels PX may include a transfer transistor TX and logic transistors RX, SX, and DX. As described above, the logic transistors may include a reset transistor RX, a select transistor SX, and a drive transistor DX. The transfer transistor TX may include a transfer gate TG. Each of the unit pixels PX may further include a photoelectric conversion region PD and a floating diffusion region FD.

Referring to FIG. 3 together with FIG. 2, the transfer transistor TX may be configured to transfer charges generated in the photoelectric conversion region 120 or PD to the floating diffusion region FD. The reset transistor RX may be configured to periodically reset charges stored in the floating diffusion region FD. The drive transistor DX is also referred to as a source follower transistor. The drive transistor DX serves as a source follower buffer amplifier and may be configured to buffer a signal according to charges charged in the floating diffusion region. The selection transistor SX may serve as a switching and addressing function for selecting the pixel PX.

Specifically, the photoelectric conversion region 120 may generate and accumulate photocharges in proportion to an amount of light incident from the outside, and may be indicated as “120,” disposed in the semiconductor substrate 110 in FIGS. 2 and 4A to 4C. The photoelectric conversion region 120 may include a photodiode, a phototransistor, a photogate, or a pinned photodiode.

The transfer transistor TG may transfer charges generated in the photoelectric conversion region PD to the floating diffusion region FD in response to the transfer control signal TS being applied to a gate terminal. The floating diffusion region FD may receive and accumulate charges generated in the photoelectric conversion region PD. The drive transistor DX may be controlled according to an amount of photocharges accumulated in the floating diffusion region FD.

The reset transistor RX may periodically reset charges accumulated in the floating diffusion region FD when a reset control signal RS is applied. A drain electrode of the reset transistor RX may be connected to the floating diffusion region FD, and a source electrode of the reset transistor RX may be connected to a power supply voltage VDD. When the reset transistor RX is turned on, the power supply voltage VDD connected to the source electrode of the reset transistor RX may be applied to the floating diffusion region FD. Therefore, when the reset transistor RX is turned on, the charges accumulated in the floating diffusion region FD may be discharged and the floating diffusion region FD may be reset.

The drive transistor DX may serve as a source follower buffer amplifier. The drive transistor DX may amplify a potential change in the floating diffusion region FD and output the same to an output line Vout.

The selection transistor SX may select unit pixels PX read in units of rows. When the selection transistor SX is turned on by a selection control signal SEL applied to a gate terminal, a power voltage VDD may be applied to a drain electrode of the drive transistor DX.

The transfer gates TG employed in this embodiment may be referred to as a dual vertical transfer gate 150 (also referred to as a ‘vertical transfer gate’).

The dual vertical transfer gate 150 may include first and second vertical electrode portions 150V1 and 150V2 extending from the first surface 110A of the semiconductor substrate 110 in a direction, perpendicular to the first surface 110A, and an electrode pad portion 150P on the first surface 110A of the semiconductor substrate 110 and connected to the first and second vertical electrode portions 150V1 and 150V2 in common.

The first and second vertical electrode portions 150V1 and 150V2 may extend into the semiconductor substrate 110 and may be connected to the photoelectric conversion region 120. The electrode pad portion 150P may sufficiently secure a contact area connected to the contact 165 (e.g., CA5).

As illustrated in FIG. 2, the electrode pad portion 150P may have a concave portion CP in a region, adjacent to the floating diffusion region FD in plan view. The vertical transfer gate 150 may secure a distance from the floating diffusion region FD (particularly, the high concentration region 116H) by the concave portion CP of the electrode pad portion 150P, and accordingly, a problem of leakage current such as GIDL between the electrode pad portion and the floating diffusion region may be effectively solved.

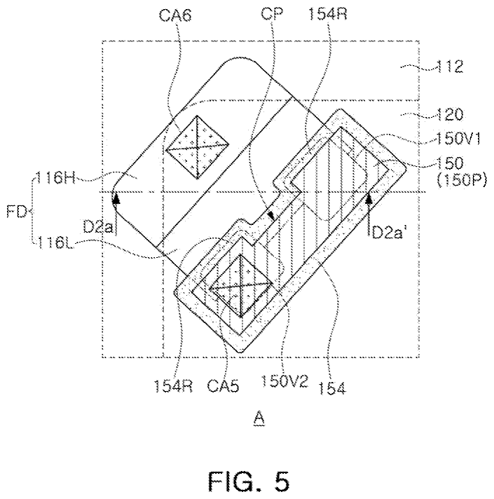

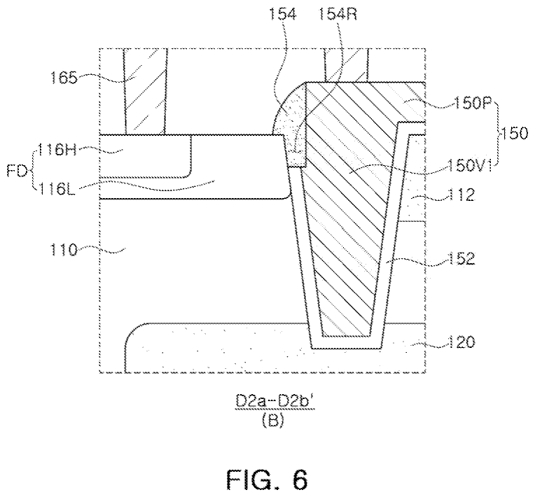

Hereinafter, a structure and effect according to the vertical transfer gate structure employed in this embodiment will be described in detail with reference to FIGS. 5 and 6.

FIG. 5 is a partially enlarged view illustrating portion “A” of the image sensor of FIG. 2, and FIG. 6 is a partially enlarged view illustrating portion “B” of the image sensor of FIG. 4B. The partially enlarged view of FIG. 6 may be understood as a cross-section of the portion of FIG. 5 cut along lines D2a-D2a′.

Referring to FIGS. 5 and 6, the floating diffusion region FD may be positioned adjacent to one side of the electrode pad portion 150P of the vertical transfer gate 150. The floating diffusion region FD may include an impurity region, adjacent to the first surface 110A of the semiconductor substrate 110 inside the semiconductor substrate 110. In this embodiment, the floating diffusion region FD may include a low concentration region 116L in contact with the vertical transfer gate 150 and a high concentration region 116H positioned within the low concentration region 116L. The low concentration region 116L may also be referred to as an active region for the floating diffusion region FD. A contact 165 (e.g., CA6) may be connected to the high concentration region 116H. In some example embodiments, the semiconductor substrate 110 may be a low-concentration P-type substrate, and the floating diffusion region FD may be an N-type impurity region.

As described above, the vertical transfer gate 150 may include an electrode pad portion 150P as a contact region of the contact 165 (e.g., CA5), and the electrode pad portion 150P may include a concave portion CP, located on a side adjacent to the floating diffusion region FD to secure a sufficient distance from the floating diffusion region FD (in particular, the high concentration region 116H).

The concave portion CP may be formed in a region (also referred to as a “bridge region”) located between portions respectively connected to the first and second vertical electrode portions 150V1 and 150V2 in the electrode pad portion 150P. As illustrated in FIG. 5, the electrode pad portion 150P may have a horizontally symmetrical structure with respect to the concave portion CP in plan view.

Referring to FIGS. 5 and 6, the vertical transfer gate 150 may further include a transfer gate insulating film 152 (also referred to as a “gate insulating film”) conformally formed on an inner wall of the gate trench 150T, and a transfer gate spacer 154 along a side surface of the electrode pad portion 150P on the first surface 110A of the semiconductor substrate 110.

The transfer gate spacer 154 may include a spacer extension portion 154R extending from the first surface 110A into the semiconductor substrate 110 between the vertical transfer gate 150 and the floating diffusion region FD. The spacer extension portion 154R may be introduced to suppress leakage current caused by GIDL by miniaturizing pixels. When viewed in plan view, the spacer extension portion 154R may extend along a portion of the concave portion CP. As illustrated in FIG. 5, the spacer extension portion 154R may extend from the concave portion CP along a region, overlapping a boundary of the upper surface of the first and second vertical electrode portions 150V1 and 150V2.

As illustrated in FIG. 6, the first and second vertical electrode portions 150V1 and 150V2 and the electrode pad portion 150P may be formed as an integrated electrode structure. Such an integrated electrode structure may include, e.g., doped polysilicon, metal, metal silicide, metal nitride, or metal-containing film. The transfer gate insulating film 152 may include silicon oxide or metal oxide, and the transfer gate spacer 154 may include silicon nitride, silicon oxynitride, or silicon oxide.

The reset gate RG, the source follower gate SF, and the select gate SEL may be referred to as a first gate electrode 140, and the first gate electrode 140 may be on a first surface 110A of the semiconductor substrate 110. In an implementation, the first gate electrode 140 may include doped polysilicon, metal, metal silicide, metal nitride, or a metal-containing film. A first gate insulating film 152 may be between the first gate electrode 140 and the semiconductor substrate 110. The first gate insulating film 152 may be formed as a continuous material layer extending into a gate trench and connected to a transfer gate insulating film 152. In some example embodiments, the first gate insulating layer 152 may extend onto the first surface 110A of the semiconductor substrate 110, but may not extend into the transfer gate trench 150T. In another example embodiment, the first gate insulating layer 152 may be formed of a material layer, separate from the transfer gate insulating layer 152.

A first source/drain region SD1 and a second source/drain region SD2 may be on both sides of the first gate electrode 140. The first source/drain region SD1 and the second source/drain region SD2 may be regions doped with impurities in a high concentration.

An interlayer insulating layer 161 may be on the first surface 110A of the semiconductor substrate 110. The interlayer insulating layer 161 may cover a ground region GND, a floating diffusion region FD, a device isolation film 112, a transfer gate electrode 150, and a first gate electrode 140. In an implementation, the interlayer insulating layer 161 may include silicon nitride or silicon oxynitride.

In some example embodiments, the interlayer insulating layer 161 may be formed as a stacked structure of a plurality of insulating layers. In some other example embodiments, an etch stop layer (not shown) may be interposed between the interlayer insulating layer 161 and the first surface 110A of the semiconductor substrate 110, and the etch stop layer may include a material having etch selectivity with respect to the interlayer insulating layer 161. A contact 165 penetrating through the interlayer insulating layer 161 may be on the first surface 110A of the semiconductor substrate 110. In an implementation, the contact 165 may be electrically connected to an active region (e.g., first and second source/drain regions SD1 and SD2), a transfer gate electrode 150, and a first gate electrode 140 through the interlayer insulating layer 161. The contact 165 may include a first contact CA1, a second contact CA2, a third contact CA3, a fourth contact CA4, and a fifth contact CA5. In an implementation, contact 165 may include tungsten, aluminum, copper, tungsten silicide, titanium silicide, tungsten nitride, titanium nitride, or doped polysilicon.

The first contact CA1 and the sixth contact CA6 may be connected to a ground region GND and a floating diffusion region FD, respectively. The third contact CA3 and the fifth contact CA5 may be connected to the first gate electrode 140 and the transfer gate electrode 150, respectively. The second contact CA2 and the third contact CA3 may be connected to the first source/drain region SD and the second source/drain region SD2, respectively.

An interconnection structure 170 may be on the interlayer insulating layer 161. The interconnection structure 170 may be formed as a stacked structure of a plurality of layers. The interconnection structure 170 may include an interconnection layer 175 and an insulating layer 171 surrounding the interconnection layer 175. In an implementation, the interconnection layer 175 may include tungsten, aluminum, or copper. The insulating layer 171 may include an insulating material such as silicon oxide, silicon nitride, or silicon oxynitride.

A rear insulating layer 182 may be on a second surface 110B of the semiconductor substrate 110. The rear insulating layer 182 may be on substantially an entire area of the second surface 110B of the semiconductor substrate 110, and the rear insulating layer 182 may be in contact with an upper surface of the isolation structure 130 on the same level as the second surface 110B of the semiconductor substrate 110. In some example embodiments, the rear insulating layer 182 may include a metal oxide such as hafnium oxide, aluminum oxide, or tantalum oxide. In other example embodiments, the rear insulating layer 182 may include an insulating material such as silicon oxide, silicon nitride, silicon oxynitride, or a low-k material. A passivation layer 184 may be on the rear insulating layer 182, and a color filter 186 and a microlens 188 may be on the passivation layer 184. Optionally, a support substrate may be further on the first surface 110A of the semiconductor substrate 110.

In general, a pixel circuit such as a reset gate RG, a select gate SEL, and a source follower gate SF in a pixel PX may be spaced apart from each other in a horizontal direction within the pixel. As a degree of integration of the image sensor 100 increases, a size of a unit pixel decreases and a size of each component of the pixel circuit may also decrease, which may result in leakage current through the pixel circuit or read noise of the pixel circuit. As a result, there is a problem in that the quality of the image sensor may be degraded. In particular, with the introduction of the dual vertical transfer gate 150, a reliability problem such as leakage current due to GIDL between the floating diffusion region FD may increase. A concave portion CP may be formed in the electrode pad portion 150P of the vertical transfer gate 150 to secure a gap with the floating diffusion region FD, thereby reducing the leakage current due to GIDL between the dual vertical transfer gate 150 and the floating diffusion region FD and effectively preventing the occurrence of read noise. Accordingly, the quality and reliability of the image sensor 100 according to the present embodiment can be improved.

The location and size of the concave portion introduced into the electrode pad portion may be variously changed according to the location and size of the floating diffusion region, adjacent thereto.

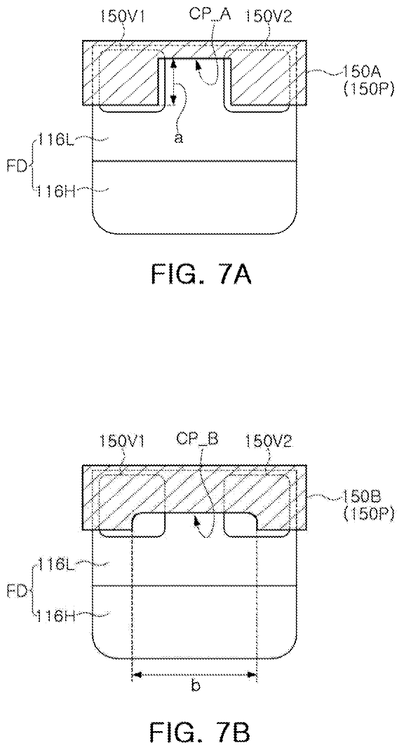

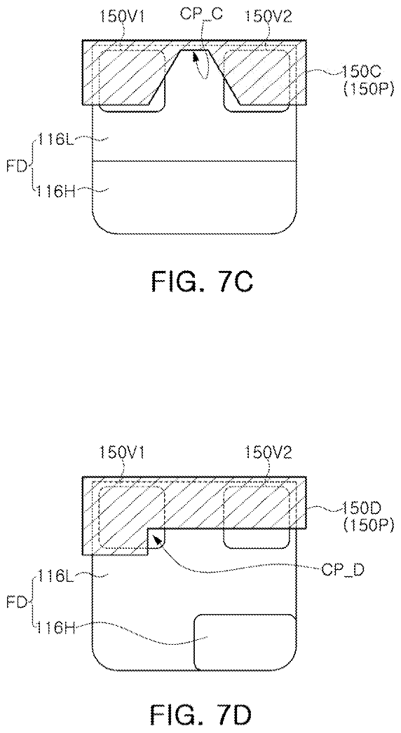

FIGS. 7A to 7D are partial layout views illustrating an image sensor according to various example embodiments. FIGS. 7A to 7D are plan views briefly illustrating an arrangement of vertical transfer gates and floating diffusion regions, similarly to the portion illustrated in FIG. 5. As in the above-described example embodiment, a gate spacer and a spacer extension portion may surround a side surface of the electrode pad portion.

Referring to FIG. 7A, the vertical transfer gate 150A according to the present example embodiment may include an electrode pad portion 150P having a concave portion CP_A having a different shape. The concave portion CP_A introduced in the present embodiment may be on a side of the electrode pad portion 150P toward the floating diffusion region FD, particularly in a bridge region, but may have a depth (a), deeper than the depth of the concave portion CP in the previous embodiment. The bridge region of the electrode pad unit 150P introduced in this embodiment may have a width, narrower than that of the bridge region of the previous embodiment.

Referring to FIG. 7B, the vertical transfer gate 150B according to the present embodiment may include an electrode pad portion 150P having a concave portion CP_B extending in a width direction. The concave portion CP_B introduced in the present embodiment may be on a side of the electrode pad portion 150P toward the floating diffusion region FD, particularly in a bridge region, but may have a width (b), greater than the width of the concave portion CP in the previous embodiment. The concave portion CP_B introduced in this embodiment may include a concave curved portion in plan view. In this embodiment, only a partial region (e.g., a corner) of the concave portion may be a rounded portion, but in another embodiment, the curved portion may constitute almost an entirety of the concave portion CP_B.

Referring to FIG. 7C, the vertical transfer gate 150C according to the present embodiment may include an electrode pad portion 150P having a concave portion CP_C whose width is changed according to the depth thereof. The concave portion CP_C introduced in this embodiment may have a width becoming narrower as a distance from the floating diffusion region FD in the electrode pad portion 150P increases.

Referring to FIG. 7D, the vertical transfer gate 150D according to the present embodiment may include an electrode pad portion 150P having an asymmetric concave portion CP_D. The concave portion CP_D introduced in this embodiment may be positioned adjacent to the second vertical electrode portion 150V2 in the electrode pad portion 150P. In this embodiment, the floating diffusion region FD may be closer to the second vertical electrode part 150V2 than to the first vertical electrode part 150V1, and the concave part CP_D may be positioned, close to the second vertical electrode portion 150V2 in the adjacent region of electrode pad portion 150P.

As described above, in the previous embodiments (FIGS. 5 and 7A to 7C), the electrode pad portion 150P may have a left-right symmetrical structure with respect to the concave portion CP_D in plan view, but the concave portion CP_D and the electrode pad portion 150P may have a left-right asymmetric structure according to the location and size of the floating diffusion region.

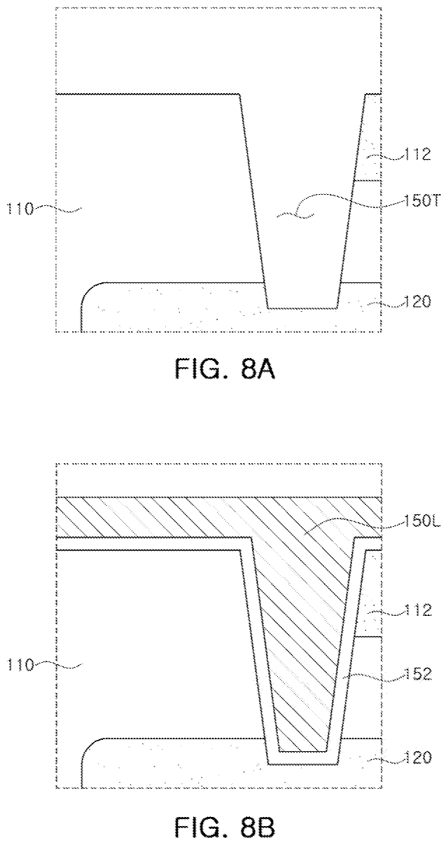

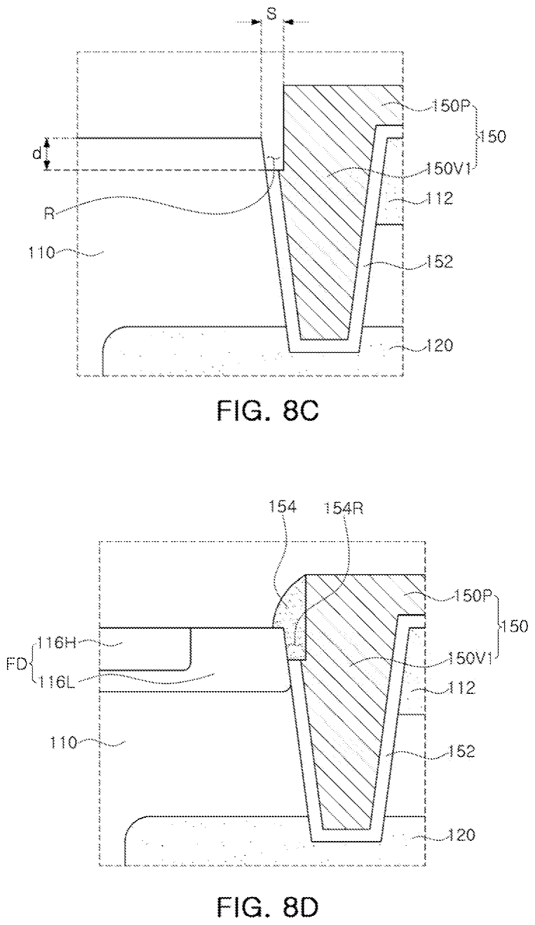

FIGS. 8A to 8D are main process cross-sectional views illustrating a method of manufacturing an image sensor according to an example embodiment.

Referring to FIG. 8A, a gate trench 150T for the vertical transfer gate 150 is formed on the semiconductor substrate 110. In the present embodiment, the gate trench 150T is two trenches for first and second vertical electrode portions 150V1 and 150V2 (see FIGS. 4C and 5). The gate trench 150T may extend from the first surface 110A of the semiconductor substrate 110 into the semiconductor substrate 110, and may be connected to the photoelectric conversion region 120.

Subsequently, referring to FIG. 8B, a gate insulating film 152 may be conformally formed on an inner wall of the gate trench 150T and the first surface 110A of the semiconductor substrate 110. In an implementation, the gate insulating film 152 may include silicon oxide or metal oxide.

Next, a gate electrode material layer 150L may be formed on the gate insulating film 152L to fill an inside of the gate trench 150T, and a planarization process such as CMP may be applied to a portion of the semiconductor substrate 110 located on the first surface 110A to have a constant thickness.

In a subsequent process (see FIG. 8C), portions thereof located on the gate trench 150T may be provided to the first and second vertical electrode portions 150V1 and 150V2, and a portion thereof located on the first surface 110A may be provided to an electrode pad portion 150P.

Next, referring to FIG. 8C, a portion of the electrode material layer 150L, located on the first surface 110A may be patterned into an electrode pad portion 150P having a desired shape by using a photo mask. As illustrated in FIG. 4, in plan view, the electrode pad portion 150P may have a concave portion CP on a side, adjacent to a floating diffusion region FD formed in a subsequent process. During a patterning process of the electrode pad portion 150P, some regions of sidewalls of the first and second vertical electrode portions 150V1 and 150V2 (e.g., a width defined as “S”) may be additionally etched to a certain depth (d), so that a recess portion R may be formed. The recess portion R may be formed in a region located on a side, adjacent to the floating diffusion region FD in the first and second vertical electrode portions 150V1 and 150V2, and extending therefrom and in some regions of sidewalls of the first and second vertical electrode portions, opposed to each other, exposed from the concave portion CP (see FIG. 4).

In this patterning process, a transfer gate insulating film 152 may be formed by removing a portion of the gate insulating film exposed through an additional etching process.

Next, referring to FIG. 8D, a transfer gate spacer 154 having a spacer extension portion 154R filled in the recess portion R may be formed. After a spacer material layer is conformally formed so that the recess portion R is filled in the first surface 110A of the semiconductor substrate 110, a transfer gate spacer 154 remaining on a sidewall of the electrode pad portion 150P may be applied by anisotropic etching. A gate spacer 154 may be formed. In an implementation, the spacer material layer may include silicon nitride, silicon oxynitride, or silicon oxide. The spacer extension portion 154R may extend from the first surface 110A into the semiconductor substrate 110 between the vertical transfer gate 150 and a floating diffusion region FD. The spacer extension portion 154R, together with the electrode pad portion 150P having the concave portion CP, may be formed despite narrowing a distance between the vertical transfer gate 150 and the floating diffusion region FD according to the integration of the image sensor, a problem of leakage current such as GIDL may be reduced.

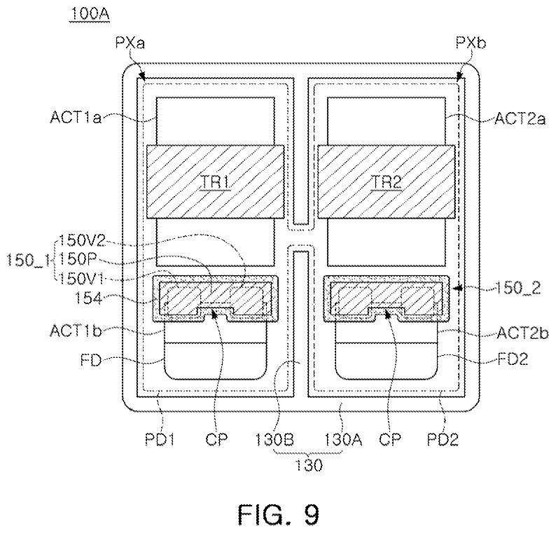

FIG. 9 is a layout diagram illustrating an image sensor according to an example embodiment. Referring to FIG. 9, it can be understood that the image sensor 100A according to the present embodiment has a structure, similar to the image sensor 100 illustrated in FIGS. 1 to 6, except for having a pixel, divided into two sub-pixels PXa and PXb and having vertical transfer gates 150_1 and 150_2 and floating diffusion regions FD1 and FD2 in each of the sub-pixels PXa and PXb. In addition, components of this embodiment may be understood with reference to descriptions of the same or similar components of the image sensor 100 illustrated in FIGS. 1 to 6 unless otherwise stated.

The image sensor according to the present embodiment may include pixels, divided into two sub-pixels PXa and PXb. The pixels illustrated in FIG. 9 may form an active pixel region (APR in FIG. 1) arranged in a plurality of rows and columns. A pixel may be divided from neighboring pixels by a first isolation structure 130A penetrating through the semiconductor substrate 110, and the first and second subpixels PXa and PXb in each pixel may be divided by a second isolation structure 130B. The second isolation structure 130B may extend from the first isolation structure 130A.

The first and second subpixels PXa and Pixy may include first active regions ACT1a and ACT2a and second active regions ACT1b and ACT2b. defined as the device isolation film 112 in FIG. 4A on the semiconductor substrate 110, respectively. Transistors TR1 and TR2 constituting a pixel circuit (see FIG. 3) and first and second floating diffusion regions FD1 and FD2 may be on the first active regions ACT1a and ACT2a and the second active regions ACT1b and ACT2b. In an implementation, the transistors TR1 and TR2 in the first active regions ACT1a and ACT2a may include a source follower gate SF, a select gate SEL, and a reset gate RG (see FIG. 2). In an implementation, first and second vertical transfer gates 150_1 and 150_2 and first and second floating diffusion regions FD may be in the second active regions ACT1b and ACT2b.

In this embodiment, the first sub-pixel PXa and the second sub-pixel PXb respectively may include a first photoelectric conversion region PD1 and a second photoelectric conversion region PD2 in the semiconductor substrate 110. In this embodiment, the first and second floating diffusion regions FD1 and FD2 may be located in one region of the first and second sub-pixels PXa and PXb, respectively, and may be formed adjacent to the first surface in the semiconductor substrate 110 (see FIG. 4B).

In the first subpixel PXa, the first vertical transfer gate 150_1 may be connected to the first photoelectric conversion region PD1. Similarly to the vertical transfer gate 150 illustrated in FIGS. 4C and 5, the first vertical transfer gate 150_1 may include a first pair of vertical electrode portions 150V1 and 150V2 connected to the first photoelectric conversion region PD1, and a first electrode pad portion 150P connected to the first pair of vertical electrode portions 150V1 and 150V2 on the semiconductor substrate 110, respectively. The first electrode pad portion 150P may have a first concave portion CP in a region, adjacent to the first floating diffusion region FD1.

Similarly thereto, in the second sub-pixel PXb, the second vertical transfer gate 150_2 may be connected to the second photoelectric conversion region PD2. The second vertical transfer gate 150_2 may include a second pair of vertical electrode portions 150V1 and 150V2 connected to the second photoelectric conversion region PD2, and a second electrode pad portion 150P respectively connected the second pair of vertical electrode portions 150V1 and 150V2 on the semiconductor substrate 110. The second electrode pad portion 150P may have a second concave portion CP in a region, adjacent to the second floating diffusion region FD2.

The first and second vertical transfer gates 150_1 and 150_2 may further include first and second gate spacers 154 alongside surfaces of the first and second electrode pad portions 150P, respectively. The first and second gate spacers 154 may include first and second spacer extension portions extending into the semiconductor substrate 110 in a region, adjacent to the first and second floating diffusion regions FD1 and FD2, respectively. The first and second spacer extensions may extend to side regions of each pair of vertical electrode portions 150V1 and 150V2, facing each other, along the first and second concave portions CP, respectively, in plan view (FIG. 5).

As described above, with the integration of image sensors and the introduction of dual vertical transfer gates, reliability problems such as leakage current due to GIDL between floating diffusion regions FD may increase. First and second concave portions CP for securing a distance from the first and second floating diffusion regions FD1 and FD2 may be formed in the electrode pad portions 150P of the first and second vertical transfer gates 150_1 and 150_2, so that the leakage current due to GIDL may be reduced. As a result, the quality and reliability of the image sensor 100 may be improved.

In an implementation, each pixel may be divided into two sub-pixels. Each pixel may be divided into four sub-pixels. In some example embodiments, the floating diffusion region may be shared by four sub-pixels.

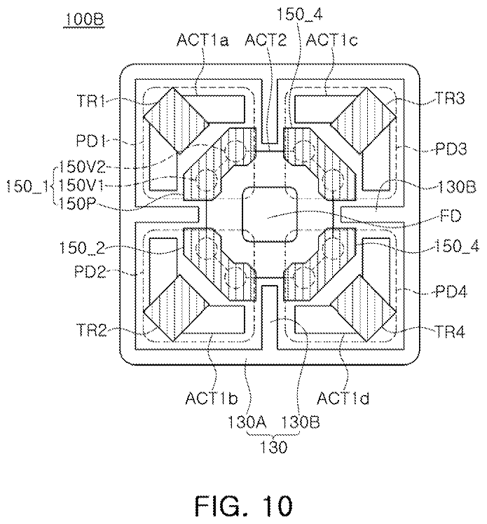

FIG. 10 is a partial layout diagram illustrating an image sensor according to an example embodiment. Referring to FIG. 10, an image sensor 100B according to the present embodiment may have a pixel divided into four sub-pixels, and the image sensor 100B may be understood as having a structure, similar to the image sensor 100 illustrated in FIGS. 1 to 6, except for having a floating diffusion region FD shared by each of the sub-pixels (e.g., vertical transfer gates 150_1, 150_2, 150_3, and 150_4). In addition, components of the present embodiment may be understood with reference to descriptions of the same or similar components to those of the image sensor 100 shown in FIGS. 1 to 6.

The image sensor according to the present embodiment may include pixels divided into four sub-pixels. As illustrated in FIG. 10, four sub-pixels may be arranged in a matrix of two rows and two columns, respectively. The pixels illustrated in FIG. 10 may form an active pixel region APR arranged in a plurality of rows and columns. The pixel illustrated in FIG. 10 may be divided from other neighboring pixels by a first isolation structure 130A, penetrating through the semiconductor substrate 110, and the first to fourth sub-pixels in each pixel may be divided by a second isolation structure 130B. The second isolation structure 130B may extend from the first isolation structure 130A. Each of the first to fourth sub-pixels may include first active regions ACT1a, ACT1b, ACT1c, and ACT1d and a second active region ACT2 defined as a device isolation layer 112 in the semiconductor substrate 110. The second active region ACT2 may be located at a center of a pixel and may be shared by sub-pixels, and the first active regions ACT1a, ACT1b, ACT1c, and ACT1d may be arranged in a mirror-mirror symmetrical or rotationally symmetrical structure toward the center of the pixel. Transistors TR1, TR2, TR3, and TR4 constituting a pixel circuit and a floating diffusion region FD may be formed on the first active regions ACT1a, ACT1b, ACT1c, and ACT1d and the second active region ACT2. In an implementation, the transistors TR1, TR2, TR3, and TR4 in the first active regions ACT1a, ACT1b, ACT1c, and ACT1d may include a source follower gate SF, a selection gate SEL, and a reset gate RG. In an implementation, first to fourth vertical transfer gates 150_1, 150_2, 150_3, and 150_4 and a floating diffusion region FD may be in the second active region ACT2.

In the present embodiment, the first to fourth sub-pixels may include first to fourth photoelectric conversion regions PD1, PD2, PD3, and PD4 in the semiconductor substrate 110, respectively. In the present embodiment, the floating diffusion region FD may be located in a central region of a pixel shared by the first to fourth sub-pixels.

The first to fourth vertical transfer gates 150_1, 150_2, 150_3, and 150_4 may be connected to the first to fourth photoelectric conversion regions PD1, PD2, PD3, and PD4 in the first to fourth sub-pixels, respectively, and as illustrated in FIG. 10, may be adjacent to the floating diffusion region FD.

Similarly to the vertical transfer gate 150 illustrated in FIGS. 4C and 5, the first vertical transfer gate 150_1 may include a first pair of vertical electrode portions 150V1 and 150V2 connected to the first photoelectric conversion region PD1, and a first electrode pad portion 150P respectively connected to the first pair of vertical electrode parts 150V1 and 150V2 on the semiconductor substrate 110.

The first electrode pad portion 150P may have a different shape optimized for a corner of the first sub-pixel rather than a rectangle in plan view, and as described above, may have a concave portion CP in a region, adjacent to the first floating diffusion region FD1. Similarly to the first vertical transfer gate 150_1, each of the second to fourth vertical transfer gates 150_2, 150_3, and 150_4 may be disposed at corners of respective sub-pixels respectively connected to the second to fourth conversion regions PD2 to PD4. In addition, the second to fourth vertical transfer gates 150_2, 150_3, and 150_4 may include a pair of vertical electrode portions 150V1 and 150V2 and a second electrode pad portion 150P, and the electrode pad portion 150P may have a concave portion CP in a region, adjacent to the floating diffusion region FD.

Each of the first to fourth vertical transfer gates 150_1, 150_2, 150_3, and 150_4 may further include first and second gate spacers 154 alongside surfaces of the first and second electrode pad portions 150P, and the first and second gate spacers 154 may include first and second spacer extension portions extending into the semiconductor substrate 110 in a region, adjacent to the first and second floating diffusion regions FD1 and FD2, respectively.

As described above, by forming the concave portion CP to secure a gap with the floating diffusion region FD in the electrode pad portion 150P of the first to fourth vertical transfer gates 150_1, 150_2, 150_3, and 150_4, leakage current due to GIDL may be reduced, and as a result, the quality and reliability of the image sensor 100 may be improved.

As set forth above, according to some example embodiments, a leakage current problem due to gate induced drain leakage (GIDL) may be effectively improved by forming a concave portion on a side, adjacent to a floating diffusion region in an electrode pad of a dual vertical transfer gate (VTG).

By way of summation and review, as a degree of integration of the image sensor increases, the size of each pixel decreases and the size of each element of the pixel circuit also decreases. Therefore, leakage current through the pixel circuit occurs, thereby causing a problem in that the quality of the image sensor may deteriorate. An image sensor may have improved reliability by improving electrical characteristics such as read noise of a pixel circuit.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An image sensor, comprising:
a semiconductor substrate having first and second surfaces opposed to each other;
a photoelectric conversion region in the semiconductor substrate;
a floating diffusion region adjacent to the first surface in the semiconductor substrate; and
a vertical transfer gate on the first surface of the semiconductor substrate, and extending in a direction perpendicular to the first surface and connected to the photoelectric conversion region, and the vertical transfer gate transferring photocharges collected in the photoelectric conversion region to the floating diffusion region,
wherein the vertical transfer gate includes:
a first vertical electrode portion and a second vertical electrode portion extending from the first surface of the semiconductor substrate in the vertical direction, and connected to the photoelectric conversion region, respectively, and
an electrode pad portion on the first surface of the semiconductor substrate, connected to the first and second vertical electrode portions, and having a concave portion adjacent to the floating diffusion region.

2. The image sensor as claimed in claim 1, wherein the concave portion is located between portions of the electrode pad portion connected to the first and second vertical electrode portions.

3. The image sensor as claimed in claim 1, wherein the vertical transfer gate further includes a transfer gate spacer along a side surface of the electrode pad portion on the first surface of the semiconductor substrate.

4. The image sensor as claimed in claim 3, wherein the transfer gate spacer includes a spacer extension portion extending into the semiconductor substrate from the first substrate between the vertical transfer gate and the floating diffusion region.

5. The image sensor as claimed in claim 4, wherein the spacer extension portion has a portion extending along the concave portion in plan view.

6. The image sensor as claimed in claim 1, wherein the vertical electrode portion and the electrode pad portion have an integrated structure containing the same material.

7. The image sensor as claimed in claim 1, wherein the concave portion includes a concave curved portion in plan view.

8. The image sensor as claimed in claim 1, wherein the electrode pad portion has a left-right symmetrical structure with respect to the concave portion in plan view.

9. The image sensor as claimed in claim 1, wherein the electrode pad portion has a left-right asymmetric structure with respect to the concave portion in plan view.

10. The image sensor as claimed in claim 9, wherein:
the floating diffusion region is closer to the second vertical electrode portion than the first vertical electrode portion, and
the concave portion is located close to the second vertical electrode portion in a region adjacent to the electrode pad portion.

11. The image sensor as claimed in claim 1, wherein:
the vertical transfer gate further includes a gate insulating film along an interface with the semiconductor substrate, and
the gate insulating film extends on the first surface of the semiconductor substrate.

12. An image sensor, comprising:
a semiconductor substrate having first and second surfaces opposed to each other and having a plurality of pixels arranged thereon;
a first isolation structure penetrating through the semiconductor substrate, and defining the plurality of pixels;
a second isolation structure penetrating through the semiconductor substrate, and dividing each of the plurality of pixels into a first sub-pixel and a second sub-pixel;
a first photoelectric conversion region and a second photoelectric conversion region in the semiconductor substrate, and respectively located in the first sub-pixel and the second sub-pixel of each of the plurality of pixels;
a first floating diffusion region and a second floating diffusion region adjacent to the first surface in the semiconductor substrate, and respectively located in the first sub-pixel and the second sub-pixel of each of the plurality of pixels;
a first vertical transfer gate, in the first sub-pixel of each of the plurality of pixels, the first vertical transfer gate having a first pair of vertical electrode portions extending from the first surface and connected to the first photoelectric conversion region, and a first electrode pad portion respectively connected to the first pair of vertical electrode portions on the first surface, and having a first concave portion in a region, adjacent to the first floating diffusion region; and
a second vertical transfer gate, in the second sub-pixel of each of the plurality of pixels, the second vertical transfer gate having a second pair of vertical electrode portions extending from the first surface and connected to the second photoelectric conversion region, and a second electrode pad portion respectively connected to the second pair of vertical electrode portions on the first surface, and having a second concave portion in a region, adjacent to the second floating diffusion region.

13. The image sensor as claimed in claim 12, wherein each of the first and second vertical transfer gates further includes:
first and second transfer gate spacers alongside surfaces of the first and second electrode pad portions on the first surface of the semiconductor substrate, and
wherein the first and second transfer gate spacers include first and second spacer extension portions extending into the semiconductor substrate from the first surface in a region, adjacent to the first and second floating diffusion regions, respectively.

14. The image sensor as claimed in claim 13, wherein:
the first and second concave portions are located in a central region on one side of the first and second pad portions, and
the first and second spacer extension portions extend along the first and second concave portions, respectively, in plan view.

15. The image sensor as claimed in claim 12, wherein the vertical electrode portion and the electrode pad portion have an integrated structure including the same material.

16. The image sensor as claimed in claim 12, wherein the first and second concave portions include a concave curved portion in plan view.

17. An image sensor, comprising:
a semiconductor substrate having first and second surfaces facing each other, and having a plurality of pixels arranged thereon;
a first isolation structure on the semiconductor substrate, and defining the plurality of pixels;
a second isolation structure penetrating through the semiconductor substrate, and dividing each of the plurality of pixels into a plurality of sub-pixels;
a plurality of photoelectric conversion regions in the semiconductor substrate in each of the plurality of sub-pixels;
a plurality of vertical transfer gates on the plurality of photoelectric conversion regions on the first surface of the semiconductor substrate, respectively, and respectively connected to the plurality of photoelectric conversion regions; and
a common floating diffusion region coupled to the plurality of vertical transfer gates,
wherein each of the plurality of vertical transfer gates, includes:
first and second vertical electrode portions extending from the first surface of the semiconductor substrate in a direction, perpendicular to the first surface, and respectively connected to each of the plurality of photoelectric conversion regions; and
an electrode pad portion on the first surface of the semiconductor substrate, connected to the first and second vertical electrode portions, and having a concave portion in a region, adjacent to the common floating diffusion region.

18. The image sensor as claimed in claim 17, wherein:
each of the plurality of pixels includes first to fourth sub-pixels,
the plurality of photoelectric conversion regions include first to fourth photoelectric conversion regions respectively in the first to fourth sub-pixels, and
the plurality of vertical transfer gates include first to fourth vertical transfer gates respectively in the first to fourth sub-pixels.

19. The image sensor as claimed in claim 18, wherein the plurality of pixels include first to fourth sub-pixels in a matrix form of two rows and two columns, respectively.

20. The image sensor as claimed in claim 19, wherein the common floating diffusion region is in a central region of each of the plurality of pixels, where the first to fourth sub-pixels meet,
the first to fourth vertical transfer gates are respectively in a region, adjacent to the central region in the first to fourth sub-pixels, respectively, and
the concave portion of each of the first to fourth vertical transfer gates is located on a side from the electrode pad portion toward the common floating diffusion region.
